(19) United States
(12) Patent Application Publication
(10) Pub. No.: US 2025/0125315 A1
(43) Pub. Date: Apr. 17, 2025

(54) MANUFACTURING METHOD OF A LIGHT-EMITTING DEVICE AND LIGHT-EMITTING DEVICE

(71) Applicant: Enkris Semiconductor, Inc., Suzhou (CN)

(72) Inventor: Kai Cheng, Suzhou (CN)

(21) Appl. No.: 18/426,874

(22) Filed: Jan. 30, 2024

(30) Foreign Application Priority Data
Oct. 11, 2023 (CN) 202311315681.6

(51) Int. Cl. H01L 25/075; H01L 33/00; H01L 33/20; H01L 33/62

(52) U.S. Cl. CPC H01L 25/0753; H10H 20/01335; H10H 20/819; H10H 20/857; H10H 20/0364

(57) ABSTRACT

A manufacturing method of a light-emitting device includes providing a substrate including a front surface and a back surface opposite to each other; performing patterning process on the front surface of the substrate to form protrusion portions and grooves; growing a semiconductor epitaxial layer on the protrusion portions and/or in the grooves and doping a first element during the growth of the semiconductor epitaxial layer to form first light-emitting units and second light-emitting units, where the component proportion of the first element in the first light-emitting units is different from the component proportion of the first element in the second light-emitting units; turning the substrate upside down on a transposition substrate to expose the back surface of the substrate; and forming third light-emitting units on the back surface of the substrate.

### CROSS-REFERENCE TO RELATED APPLICATION(S)

This application claims priority to Chinese Patent Application No. 202311315681.6 filed Oct. 11, 2023, the disclosure of which is incorporated herein by reference in its entirety.

### TECHNICAL FIELD

Embodiments of the present disclosure relate to the field of semiconductor technology and, in particular, to a manufacturing method of a light-emitting device and a light-emitting device.

### BACKGROUND

Micro-led uses a blue light-emitting structure to excite red and green quantum dots to implement full-color display. Compared with conventional LED display, the Micro-led has higher image brightness, higher image contrast, richer dark field details, and more accurate color restoration.

In the related art, the light-emitting layer in an LED is implemented by wavelength conversion using phosphor powder or quantum dots. The disadvantages of this method are that the phosphor powder or quantum dots have a short service life, and there is a problem in light conversion efficiency. Furthermore, monochromatic LEDs are separately manufactured and then transferred to a driving substrate. The process is cumbersome. As a result, the yield of the obtained product is low.

### SUMMARY

Embodiments of the present disclosure provide a manufacturing method of a light-emitting device and a light-emitting device.

According to an aspect of the present disclosure, a manufacturing method of a light-emitting device and a light-emitting device are provided. The method includes the steps below.

A substrate is provided. The substrate includes a front surface and a back surface opposite to each other.

Patterning process is performed on the front surface of the substrate to form protrusion portions and grooves.

A semiconductor epitaxial layer is grown on the protrusion portions and/or in the grooves. A first element is doped during the growth of the semiconductor epitaxial layer to form multiple first light-emitting units and multiple second light-emitting units. The component proportion of the first element in the first light-emitting units is different from the component proportion of the first element in the second light-emitting units.

The substrate is turned upside down on a transposition substrate to expose the back surface of the substrate.

Multiple third light-emitting units are formed on the back surface of the substrate.

According to another aspect of the present disclosure, a light-emitting device is provided. The device includes a substrate, multiple first light-emitting units and multiple second light-emitting units, and multiple third light-emitting units.

The substrate includes a front surface and a back surface opposite to each other. The front surface includes protrusion portions and grooves.

The multiple first light-emitting units and multiple second light-emitting units are located on the front surface of the substrate. The first light-emitting units and second light-emitting units are located on the protrusion portions and/or in the grooves. The component proportion of the first element in the first light-emitting units is different from the component proportion of the first element in the second light-emitting units.

The multiple third light-emitting units are located on the back surface of the substrate.

### BRIEF DESCRIPTION OF DRAWINGS

FIG. 1 is a flowchart of a manufacturing method of a light-emitting device according to an embodiment of the present disclosure.

FIG. 2 is a flowchart of another manufacturing method of a light-emitting device according to an embodiment of the present disclosure.

FIGS. 3 to 9 are sectional views corresponding to steps S210 to S270 in a manufacturing method of a light-emitting device according to an embodiment of the present disclosure.

FIG. 10 is another sectional view corresponding to step S220 in a manufacturing method of a light-emitting device according to an embodiment of the present disclosure.

FIG. 11 is a flowchart of another manufacturing method of a light-emitting device according to an embodiment of the present disclosure.

FIGS. 12 to 20 are sectional views corresponding to steps S320 to S3100 in a manufacturing method of a light-emitting device according to an embodiment of the present disclosure.

FIG. 21 is a flowchart of another manufacturing method of a light-emitting device according to an embodiment of the present disclosure.

FIGS. 22 to 30 are sectional views corresponding to steps S420 to S4110 in a manufacturing method of a light-emitting device according to an embodiment of the present disclosure.

### DETAILED DESCRIPTION

For a better understanding of the solution of the present disclosure by those skilled in the art, the technical solutions in embodiments of the present disclosure are described clearly and completely in conjunction with the drawings in the embodiments of the present disclosure. Apparently, the embodiments described are part, not all, of the embodiments of the present disclosure.

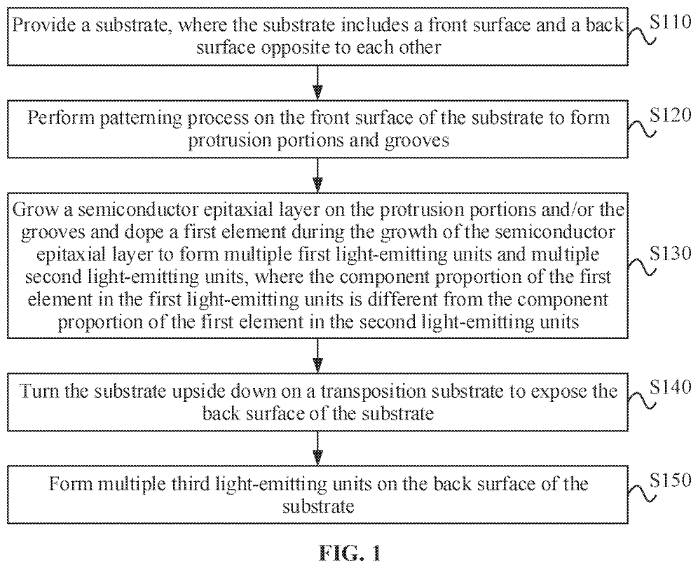

An embodiment of the present disclosure provides a manufacturing method of a light-emitting device. FIG. 1 is a flowchart of a manufacturing method of a light-emitting device according to an embodiment of the present disclosure. Referring to FIG. 1, the manufacturing method of a light-emitting device includes the steps below.

In S110, a substrate is provided. The substrate includes a front surface and a back surface opposite to each other.

Illustratively, the material of the substrate may be a material such as sapphire, silicon carbide, silicon, GaN, AlN, or diamond or a combination thereof. This is not limited in this embodiment.

In S120, patterning process is performed on the front surface of the substrate to form protrusion portions and grooves.

Illustratively, patterning process is performed on the front surface of the substrate by etching to form the protrusion portions and the grooves on the front surface of the substrate, so that the front surface of the substrate becomes an uneven surface.

In S130, a semiconductor epitaxial layer is grown on the protrusion portions and/or in the grooves. A first element is doped during the growth of the semiconductor epitaxial layer to form multiple first light-emitting units and multiple second light-emitting units. The component proportion of the first element in the first light-emitting units is different from the component proportion of the first element in the second light-emitting units.

Illustratively, the semiconductor epitaxial layer is grown on the protrusion portions, or the semiconductor epitaxial layer is grown in the grooves, or the semiconductor epitaxial layer is grown on the protrusion portions and in the grooves. The first element is doped during the growth of the semiconductor epitaxial layer to form multiple first light-emitting units and multiple second light-emitting units. It is to be understood that in an embodiment, the first light-emitting units and second light-emitting units may all be located on the protrusion portions or may all be located in the grooves; in another embodiment, part of the light-emitting units may be located on the protrusion portions, and part of the light-emitting units may be located in the grooves. The component proportion of the first element in the first light-emitting units is different from the component proportion of the first element in the second light-emitting units, so that the front surface of the substrate has light-emitting units with two emission wavelengths at the same time.

For example, a first light-emitting unit may be a blue light-emitting unit that emits blue light, and a second light-emitting unit may be a green light-emitting unit that emits green light. If the first element is In, the component proportion of the first element in the first light-emitting units is smaller than the component proportion of the first element in the second light-emitting units. If the first element is Al, the component proportion of the first element in the first light-emitting units is larger than the component proportion of the first element in the second light-emitting units. In other embodiments, other first elements may also be doped.

In S140, the substrate is turned upside down on a transposition substrate to expose the back surface of the substrate.

Illustratively, before turning upside down the substrate on the transposition substrate, a first passivation layer may be formed on the front surface of the substrate. The first passivation layer at least covers a surface of the first light-emitting units and the second light-emitting units to ensure that the substrate may be smoothly turned upside down on the transposition substrate, which is beneficial to subsequent processes.

In S150, multiple third light-emitting units are formed on the back surface of the substrate.

Illustratively, the emitted color of a third light-emitting unit is different from the emitted color of a first light-emitting unit and the emitted color of a second light-emitting unit. For example, the first light-emitting unit is a blue light-emitting unit, the second light-emitting unit is a green light-emitting unit, and the emitted color of the third light-emitting unit may be red.

In the manufacturing method of a light-emitting device provided by this embodiment of the present disclosure, multiple first light-emitting units and multiple second light-emitting units are simultaneously prepared on the front surface of the substrate, thereby improving the production efficiency of the light-emitting device. The multiple third light-emitting units are prepared on the back surface of the substrate. In this manner, light-emitting units of different colors may be transferred to a driving substrate synchronously through the transposition substrate, thereby further improving the production yield of the light-emitting device. Moreover, the first element is doped during the growth of the semiconductor epitaxial layer to form multiple first light-emitting units and multiple second light-emitting units, and the components of the light-emitting layers corresponding to different positions on the front surface are controlled to be different to form the first light-emitting units and the second light-emitting units with different emission wavelengths, therefore, there is no need to use phosphor powder or quantum dots for wavelength conversion. Thus, the service life of the light-emitting device is prolonged, and the reliability of the light-emitting device is improved.

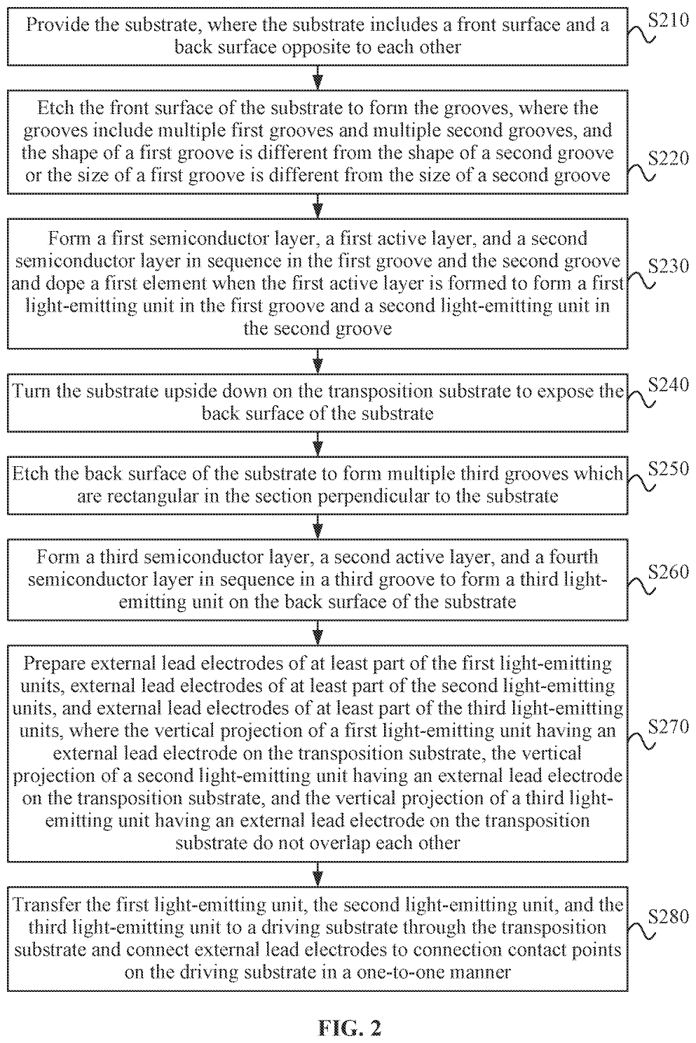

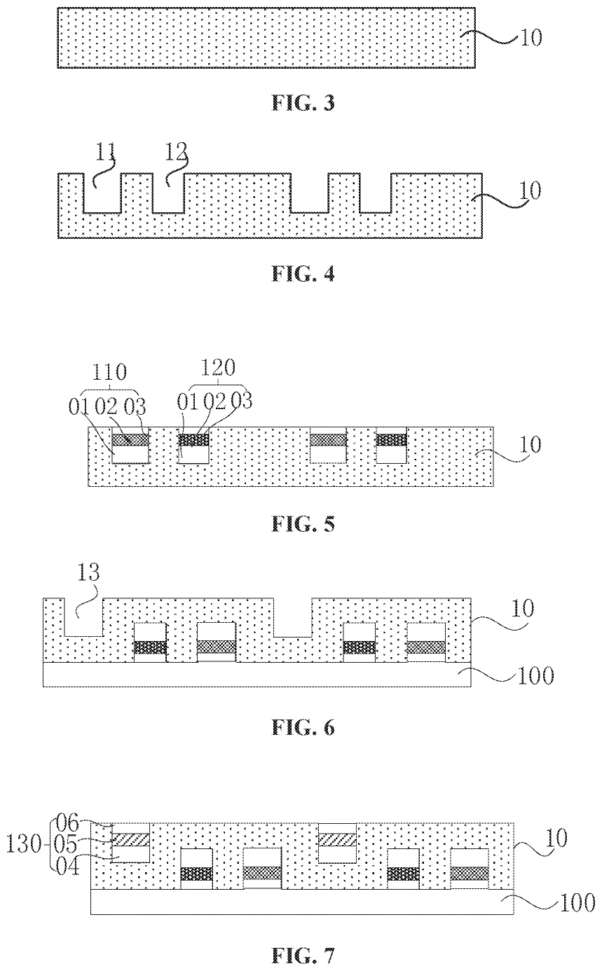

For example, FIG. 2 is a flowchart of another manufacturing method of a light-emitting device according to an embodiment of the present disclosure. FIGS. 3 to 9 are sectional views corresponding to steps S210 to S270 in a manufacturing method of a light-emitting device according to an embodiment of the present disclosure. Referring to FIG. 2, the manufacturing method of a light-emitting device includes the steps below.

In S210, the substrate is provided. The substrate includes a front surface and a back surface opposite to each other.

Illustratively, referring to FIG. 3, the material of the substrate 10 may be a material such as sapphire, silicon carbide, silicon, GaN, AlN, or diamond. This is not limited in this embodiment.

In S220, the front surface of the substrate is etched to form grooves. The grooves include multiple first grooves and multiple second grooves. The shape of a first groove is different from the shape of a second groove or the size of a first groove is different from the size of a second groove.

In S230, a first semiconductor layer, a first active layer, and a second semiconductor layer is formed in sequence in the first groove and the second groove. The first element is doped when the first active layer is formed in the first groove to form a first light-emitting unit in the first groove and the first element is doped when the first active layer is formed in the second groove to form a second light-emitting unit in the second groove. Illustratively, in grooves with different shapes or different sizes, first active layers doped with different contents of the first element are formed so as to form light-emitting units with different emission wavelengths.

Optionally, referring to FIG. 5, in step S220, the size of the formed first groove is different from the size of the formed second groove. In an example, the notch area of the first groove is larger than the notch area of the second groove. Thus, the flow rate of the reaction gas in the first groove is different from the flow rate of the reaction gas in the second groove when the first element is doped, so that the doping rate of In/Al element is different from the doping rate of Ga element, that is, the doping efficiency of In/Al element is different. Thus, the component proportion of In/Al element of the first active layer 02 grown in the first groove is different from the component proportion of In/Al element of the first active layer 02 grown in the second groove. Further, the wavelength of the light emitted by the first light-emitting unit 110 is different from the wavelength of the light emitted by the second light-emitting unit 120.

Illustratively, in the section perpendicular to the substrate, a groove is rectangular, triangular, or trapezoidal. When the substrate is viewed from above, the shapes of the first groove and the second groove may be circular, square, or hexagonal. A first semiconductor layer 01, a first active layer 02, and a second semiconductor layer 03 are epitaxially grown in sequence in each groove. The conductivity type of the second semiconductor layer 03 is opposite to the conductivity type of the first semiconductor layer 01. The material of the first semiconductor layer 01 may be group III-V nitride and may include at least one of GaN or AlGaN. The material of the second semiconductor layer 03 may be group III-V nitride and may include at least one of GaN or AlGaN. In an embodiment, the first semiconductor layer 01 may be a p-type semiconductor layer, and the second semiconductor layer 03 may be an n-type semiconductor layer. In some other embodiments, the first semiconductor layer 01 may be an n-type semiconductor layer, and the second semiconductor layer 03 may be a p-type semiconductor layer.

The first active layer 02 may include at least one of a single quantum well structure, a multi-quantum well (MQW) structure, a quantum wire structure, or a quantum dot structure. The material of the first active layer 02 may be a GaN-based material, which may be doped with In element, for example, InGaNin; and may also be doped with Al element, for example, AlGaN. The band gap of InN is about 0.7 eV and is smaller than the band gap of GaN, where the band gap of GaN is 3.4 eV. Thus, the larger the doping amount of In is, the longer the emission wavelength of the first active layer 02 is. The band gap of AlN is about 6.2 eV and is larger than the band gap of GaN, where the band gap of GaN is 3.4 eV. Thus, the larger the doping amount of Al is, the shorter the emission wavelength of the first active layer 02 is.

It is to be noted that the first groove is used as an example. The notch area refers to the opening area of the first groove when the substrate is viewed from above.

When In element is doped in base material GaN of the first active layer 02, the smaller the notch area of a groove is, the better the selectivity of the doping of In element is, so that the doping rate of In element is larger than the doping rate of Ga element. Thus, the smaller the notch area of the groove is, the higher the component content of In element in InGaN of the first active layer 02 is. In addition, the smaller the notch area of the groove is, the thickness of the quantum well in the groove increases accordingly. Due to the quantum Stark effect, an emission wavelength increases accordingly. On the contrary, the larger the notch area of the groove is, the less significant the difference between the doping rate of In element and the doping rate of Ga element is, that is, the lower the doping efficiency of In element is, the lower the component proportion of In element in the grown first active layer 02 is. In this embodiment of the present disclosure, the notch area of the first groove is larger than the notch area of the second groove. That is, the component proportion of In element in the first groove is lower than the component proportion of In element in the second groove. The wavelength of the first light-emitting unit in the first groove is smaller than the wavelength of the second light-emitting unit in the second groove. The first light-emitting unit may be a blue light-emitting unit. The second light-emitting unit may be a green light-emitting unit.

When Al element is doped in base material GaN of the first active layer 02, the smaller the notch area of the groove is, the less the selectivity of the growth of Al element is, so that the doping rate of Al element is smaller than the doping rate of Ga element. Thus, the smaller the notch area of the groove is, the lower the component content of Al element in AlGaN of the first active layer 02 is. Thus, the smaller the doping amount of Al is, the longer the emission wavelength of the first active layer 02 is. In addition, the larger the notch area of the groove is, the smaller the thickness of the grown first active layer 02 is; and the smaller the notch area of the groove is, the larger the thickness of the grown first active layer 02 is, and the thickness of the quantum well increases accordingly. Due to the quantum Stark effect, the emission wavelength may increase accordingly. In this embodiment of the present disclosure, the notch area of the first groove is larger than the notch area of the second groove. That is, the component proportion of Al element in the first groove is larger than the component proportion of Al element in the second groove. The wavelength of the first light-emitting unit in the first groove is smaller than the wavelength of the second light-emitting unit in the second groove. The first light-emitting unit may be a blue light-emitting unit. The second light-emitting unit may be a green light-emitting unit.

The bottom surface of the first groove (11) is an inclined surface. The bottom surface of the second groove (12) is parallel to the plane in which the substrate (10) is located.

In S240, the substrate is turned upside down on the transposition substrate to expose the back surface of the substrate.

Illustratively, referring to FIG. 6, the substrate 10 is turned upside down on the transposition substrate 100 to expose the back surface of the substrate 10.

In S250, the back surface of the substrate is etched to form multiple third grooves that are rectangular in the section perpendicular to the substrate.

Illustratively, further referring to FIG. 6, the back surface of the substrate 10 is etched to form multiple third grooves 13.

In S260, a third semiconductor layer, a second active layer, and a fourth semiconductor layer are formed in sequence in a third groove to form a third light-emitting unit on the back surface of the substrate.

Illustratively, referring to FIG. 7, the third semiconductor layer 04, the second active layer 05, and the fourth semiconductor layer 06 are formed in sequence in the third groove 13 to form the third light-emitting unit 130 on the back surface of the substrate 10. Illustratively, for the materials of the third semiconductor layer 04 and the fourth semiconductor layer 06, reference may be made to the materials of the first semiconductor layer 01 and the second semiconductor layer 03 in the preceding embodiment, and the details are not repeated here. The conductivity type of the third semiconductor layer 04 is opposite to the conductivity type of the fourth semiconductor layer 06. Illustratively, the second active layer 05 may be referred to the first active layer 02 in the preceding embodiment, and the details are not repeated here. Illustratively, the third groove 13 is rectangular, triangular, or trapezoidal in the section perpendicular to the substrate 10.

In S270, external lead electrodes of at least part of the first light-emitting units, external lead electrodes of at least part of the second light-emitting units, and external lead electrodes of at least part of the third light-emitting units are prepared. The vertical projection of a first light-emitting unit having an external lead electrode on the transposition substrate, the vertical projection of a second light-emitting unit having an external lead electrode on the transposition substrate, and the vertical projection of a third light-emitting unit having an external lead electrode on the transposition substrate do not overlap each other.

Illustratively, referring to FIG. 8, the first active layer 02 is located between the first semiconductor layer 01 and the second semiconductor layer 03, the second active layer 05 is located between the third semiconductor layer 04 and the fourth semiconductor layer 06. The external lead electrode of a first light-emitting unit 110 is prepared in the following manners: A first positive electrode hole and a first negative electrode hole are formed on the side of the first light-emitting unit 110 facing away from the transposition substrate 100, where one of the first positive electrode hole and the first negative electrode hole is etched to the first semiconductor layer 01 of the first light-emitting unit 110, and the other one of the first positive electrode hole and the first negative electrode hole is etched to the second semiconductor layer 03 of the first light-emitting unit 110; and insulating layers are formed on the hole walls of the first positive electrode hole and the first negative electrode hole, and a first external lead positive electrode B1 is formed in the first positive electrode hole, and a first external lead negative electrode B2 is formed in the first negative electrode hole. Similarly, a second external lead positive electrode G1 electrically connected to the first semiconductor layer 01 of the second light-emitting unit 120 and a second external lead negative electrode G2 electrically connected to the second semiconductor layer 03 of the second light-emitting unit 120 are prepared, and a third external lead positive electrode R1 electrically connected to the fourth semiconductor layer 06 of the third light-emitting unit 130 and a third external lead negative electrode R2 electrically connected to the third semiconductor layer 04 of the third light-emitting unit 130 are prepared.

In S280, the first light-emitting unit, the second light-emitting unit, and the third light-emitting unit are transferred to the driving substrate through the transposition substrate, and external lead electrodes are connected to connection contact points on the driving substrate in a one-to-one manner.

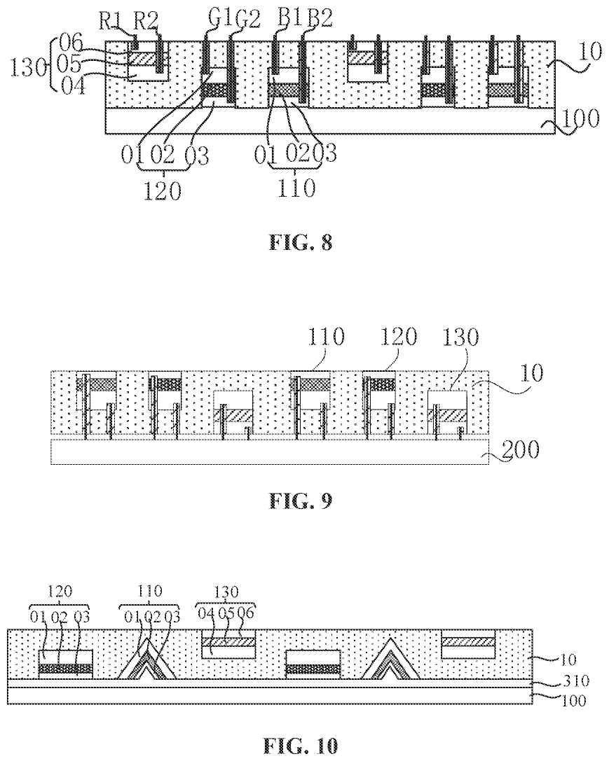

Illustratively, referring to FIG. 9, the first light-emitting unit 110, the second light-emitting unit 120, and the third light-emitting unit 130 are transferred to the driving substrate 200 through the transposition substrate 100, and external lead electrodes are connected to connection contact points on the driving substrate 200 in a one-to-one manner.

For example, in a light-emitting device manufactured referring to FIGS. 3 to 9, the front surface of the substrate 10 includes grooves. The grooves include multiple first grooves 11 and multiple second grooves 12. The shape of a first groove 11 is different from the shape of a second groove 12 or the size of a first groove 11 is different from the size of a second groove 12. Illustratively, different notch areas are used as an example, the first light-emitting units 110 are located in the first grooves 11, the second light-emitting units 120 are located in the second grooves 12. Moreover/Alternatively, the back surface of the substrate 10 includes multiple third grooves 13, and the third light-emitting units 130 are located in the third grooves 13.

Optionally, FIG. 10 is another sectional view corresponding to step S220 in a manufacturing method of a light-emitting device according to an embodiment of the present disclosure. Referring to FIG. 10, in step S220, the shape of the formed first groove 11 is different from the shape of the formed second groove 12. The bottom surface of the first groove 11 is an inclined surface. The bottom surface of the second groove 12 is parallel to the plane in which the substrate 10 is located. Thus, the doping rate of the first element in the first groove is different from the doping rate of the first element in the second groove, so that the wavelength of the light emitted by the first light-emitting unit 110 and the wavelength of the light emitted by the second light-emitting unit 120 are different.

Optionally, referring to FIG. 9, in the surface perpendicular to the plane where the substrate 10 is located, a vertical projection of the first grooves 11 overlaps a vertical projection of the third grooves 13. Similarly, the second grooves 12 overlap the third grooves 13. With this configuration, the distance between the third light-emitting unit and the first light-emitting unit and the distance between the third light-emitting unit and the second light-emitting unit in the direction perpendicular to the substrate may be reduced. The height difference between the light emission surface of the first light-emitting unit and the light emission surface of the third light-emitting unit and the height difference between the light emission surface of the second light-emitting unit and the light emission surface of the third light-emitting unit may be reduced as much as possible. Thus, the light emission effect is improved. Optionally, before the third light-emitting unit is prepared on the back surface, there is no need to thin the substrate so as to simplify the process.

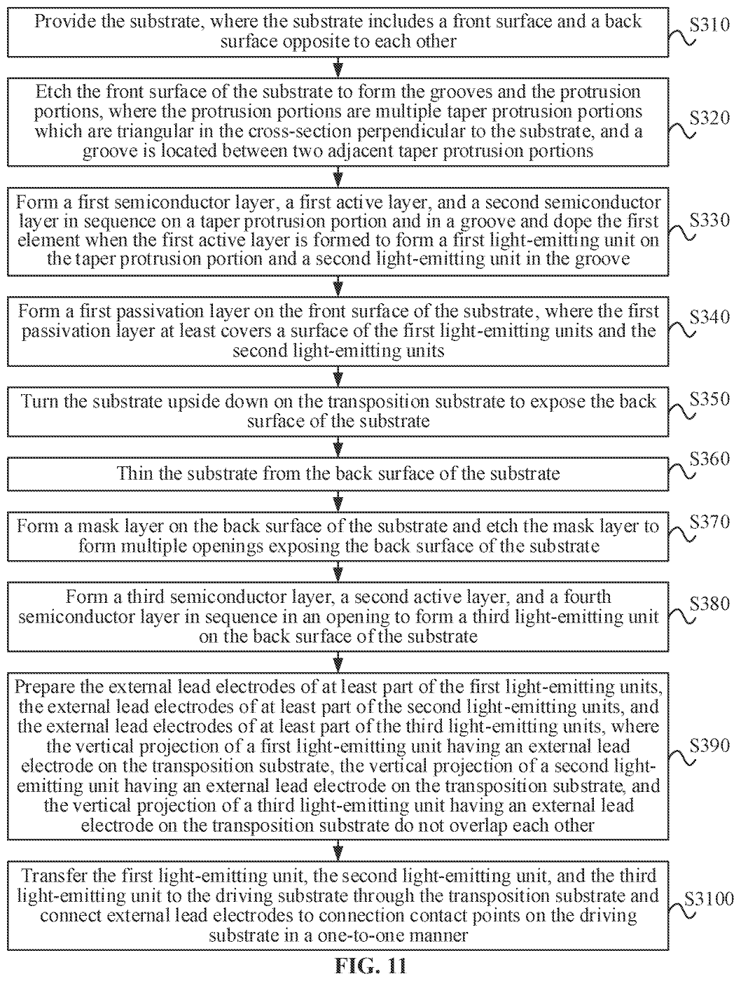

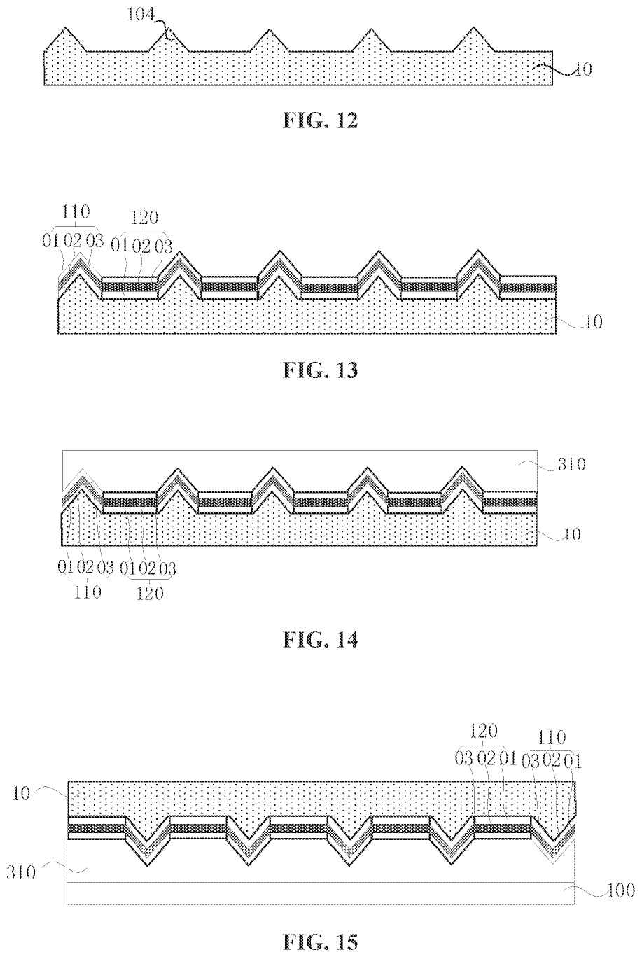

For example, FIG. 11 is a flowchart of another manufacturing method of a light-emitting device according to an embodiment of the present disclosure. FIGS. 12 to 20 are sectional views corresponding to steps S320 to S3100 in a manufacturing method of a light-emitting device according to an embodiment of the present disclosure. Referring to FIG. 11, the manufacturing method of a light-emitting device includes the steps below.

In S310, the substrate is provided. The substrate includes a front surface and a back surface opposite to each other.

In S320, the front surface of the substrate is etched to form protrusion portions and grooves. The protrusion portions are multiple taper protrusion portions which are triangular in the cross-section of the substrate perpendicular to the substrate. A groove is located between two adjacent taper protrusion portions.

Illustratively, referring to FIG. 12, the front surface of the substrate 10 is etched to form multiple taper protrusion portions 104 which are triangular in the cross-section of the substrate perpendicular to the substrate 10. A groove is located between two adjacent taper protrusion portions 104. Optionally, the substrate 10 is a single substrate made of GaN; or, the substrate 10 is a composite substrate composed of underlying silicon and taper protrusion portions 104 made of GaN.

In S330, a first semiconductor layer, a first active layer, and a second semiconductor layer is formed in sequence on a taper protrusion portion and in a groove. The first element is doped when the first active layer is formed on the taper protrusion portion to form a first light-emitting unit on the taper protrusion portion and the first element is doped when the first active layer is formed in the groove to form a second light-emitting unit in the groove.

Illustratively, referring to FIG. 13, the first semiconductor layer 01, the first active layer 02, and the second semiconductor layer 03 are formed in sequence on the taper protrusion portion 104 and in the groove, and the first element is doped when the first active layer 02 is formed. The taper protrusion portion 104 and the groove are at different heights, so that there is a difference between the growth temperature of the taper protrusion portion 104 and the growth temperature of the groove. Due to reasons such as a temperature and a position, the doping efficiency of the first element doped on the taper protrusion portion 104 and the doping efficiency of the first element doped in the groove are different. Thus, the component proportion of the first element in the first active layer 02 grown in the taper protrusion portion 104 is different from the component proportion of the first element in the first active layer 02 grown in the groove, so that the first light-emitting unit 110 and the second light-emitting unit 120 can emit light of different wavelengths. For materials of the first semiconductor layer 01, the first active layer 02, and the second semiconductor layer 03, reference may be made to the preceding embodiment, and the details are not repeated here.

In S340, the first passivation layer is formed on the front surface of the substrate. The first passivation layer at least covers a surface of the first light-emitting units and the second light-emitting units.

Illustratively, referring to FIG. 14, the first passivation layer 310 is provided to protect the first light-emitting units 110 and the second light-emitting units 120 against abrasion to the first light-emitting units 110 and the second light-emitting units 120 during transposition. In addition, the surface of the first passivation layer 310 on the side far away from the substrate may be a flat surface. Thus, the first passivation layer 310 may also function as planarization to ensure that the substrate 10 can be smoothly turned upside down on the transposition substrate 100, which is beneficial to subsequent processes.

In S350, the substrate is turned upside down on the transposition substrate to expose the back surface of the substrate.

Illustratively, referring to FIG. 15, the substrate 10 is turned upside down on the transposition substrate 100 to expose the back surface of the substrate 10.

In S360, the substrate is thinned from the back surface of the substrate.

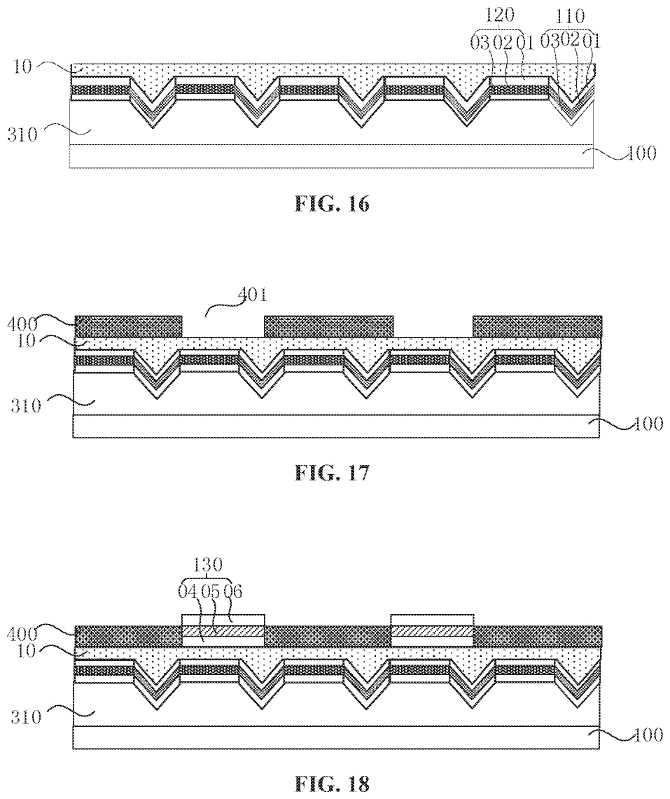

Illustratively, referring to FIG. 16, the substrate 10 is thinned. In this manner, the overall thickness of the light-emitting device may be reduced, which is beneficial to make the device thin and light. In addition, by thinning the substrate 10, the light transmittance of the substrate 10 may be improved, and the transparent display is implemented. For example, the material of the substrate 10 is sapphire, and the sapphire has good light transmittance. By thinning the substrate 10, the light transmittance of the substrate 10 may be further improved, and the transparent display is implemented. For example, the material of the substrate 10 is Si, And Si has poor light transmittance. By thinning the substrate 10, the light transmittance of the substrate 10 may be improved.

In S370, a mask layer is formed on the back surface of the substrate. The mask layer is etched to form multiple openings exposing the back surface of the substrate.

Illustratively, referring to FIG. 17, the mask layer 400 is formed on the back surface of the substrate. The mask layer 400 is etched to form multiple openings 401 exposing the back surface of the substrate 10. The material of the mask layer 400 may be nitride or oxide, such as at least one of silicon dioxide or silicon nitride. The mask layer 400 may be formed by physical vapor deposition or chemical vapor deposition. Patterning process may be implemented by dry etching or wet etching.

In S380, a third semiconductor layer, a second active layer, and a fourth semiconductor layer are formed in sequence in an opening to form a third light-emitting unit on the back surface of the substrate.

Illustratively, referring to FIG. 18, the third semiconductor layer 04, the second active layer 05, and the fourth semiconductor layer 06 are formed in sequence in the opening 401 to form the third light-emitting unit 130 on the back surface of the substrate 10. The conductivity type of the third semiconductor layer 04 is opposite to the conductivity type of the fourth semiconductor layer 06. For materials of the third semiconductor layer 04, the second active layer 05, and the fourth semiconductor layer 06, reference may be made to the preceding embodiment, and the details are not repeated here.

In S390, the external lead electrodes of at least part of the first light-emitting units, the external lead electrodes of at least part of the second light-emitting units, and the external lead electrodes of at least part of the third light-emitting units are prepared. The vertical projection of a first light-emitting unit having an external lead electrode on the transposition substrate, the vertical projection of a second light-emitting unit having an external lead electrode on the transposition substrate, and the vertical projection of a third light-emitting unit having an external lead electrode on the transposition substrate do not overlap each other.

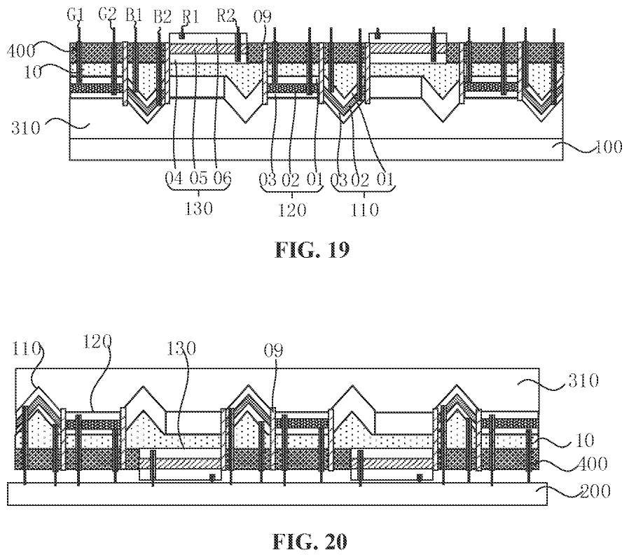

Illustratively, referring to FIG. 19, a first external lead positive electrode B1 and a first external lead negative electrode B2 of the first light-emitting unit 110 are prepared; a second external lead positive electrode G1 and a second external lead negative electrode G2 of the second light-emitting unit 120 are prepared; and a third external lead positive electrode R1 and a third external lead negative electrode R2 of the third light-emitting unit 130 are prepared. For the preparation process, reference may be made to step S270, and the details are not repeated here.

Optionally, a second insulating bank 09 is formed between adjacent first light-emitting unit 110 and second light-emitting unit 120 to prevent electrical signal crosstalk and light crosstalk between the first light-emitting unit 110 and the second light-emitting unit 120. When the second insulating bank 09 is made of an opaque material, light crosstalk between light-emitting units can be prevented.

In S3100, the first light-emitting unit, the second light-emitting unit, and the third light-emitting unit are transferred to the driving substrate through the transposition substrate, and external lead electrodes are connected to connection contact points on the driving substrate in a one-to-one manner.

Illustratively, referring to FIG. 20, the first light-emitting unit 110, the second light-emitting unit 120, and the third light-emitting unit 130 are transferred to the driving substrate 200 through the transposition substrate 100, and external lead electrodes are connected to connection contact points on the driving substrate 200 in a one-to-one manner.

For example, in a light-emitting device manufactured referring to FIGS. 12 to 20, the front surface of the substrate 10 includes protrusion portions and grooves. The protrusion portions include multiple taper protrusion portions 104 disposed at intervals. A groove is located between two adjacent taper protrusion portions 104. Illustratively, the first light-emitting units 110 are located on the surfaces of the taper protrusion portions 104, the second light-emitting units 120 are located in the grooves. Moreover/Alternatively, the back surface of the substrate 10 is provided with the mask layer 400, the mask layer 400 includes multiple openings 401 exposing the back surface of the substrate 10, and the third light-emitting units 130 are located in the openings 401.

Illustratively, after the substrate is thinned, the mask layer is formed on the back surface of the substrate. The mask layer is etched to form multiple openings exposing the back surface of the substrate. A third light-emitting unit is formed in an opening. There is no need to etch the back surface of the substrate. Thus, it is possible to prevent the difficulty in controlling the etching depth and position when the back surface of the substrate is etched from affecting the qualification rate of device preparation.

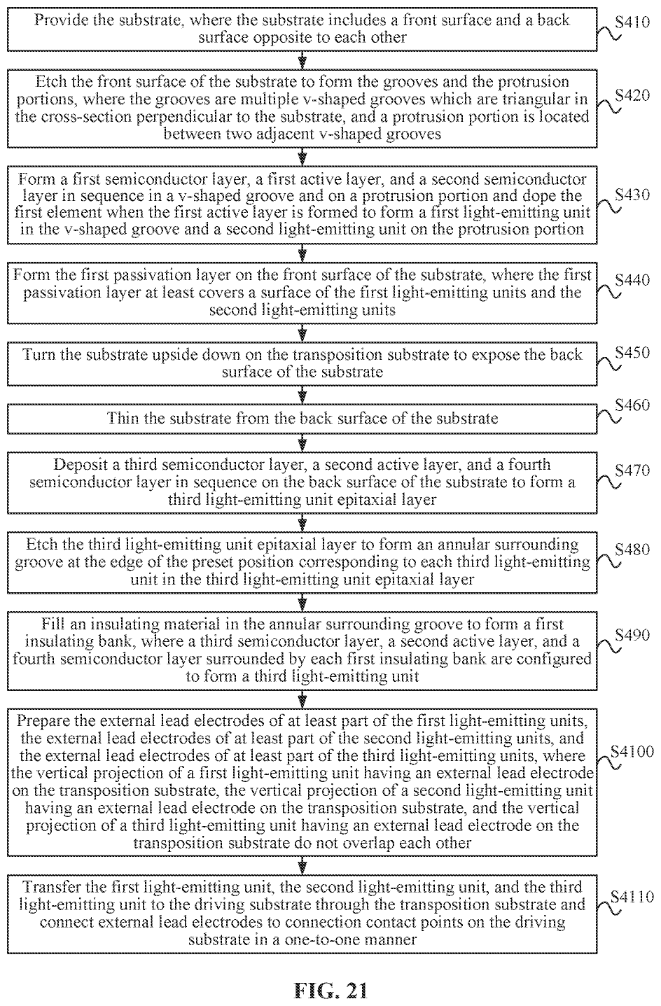

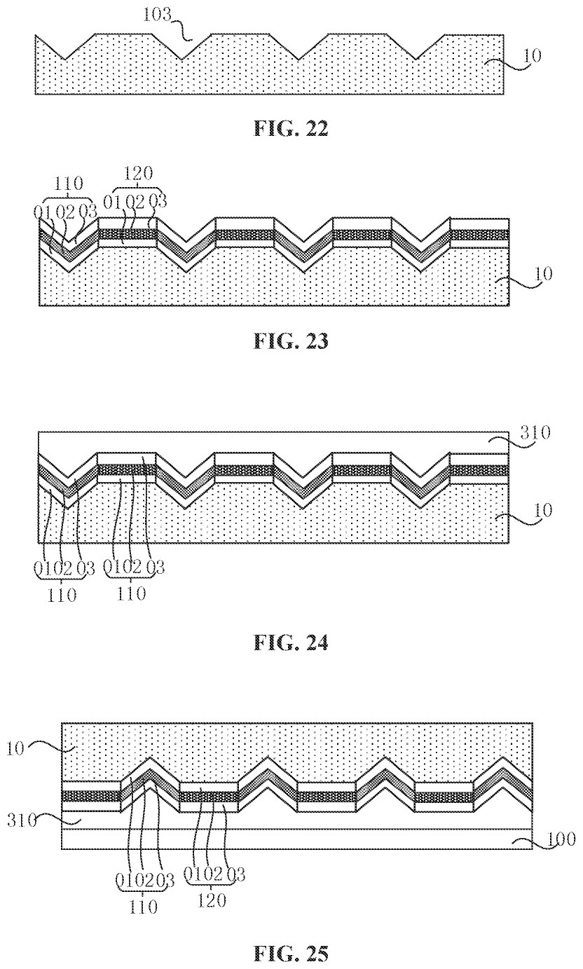

For example, FIG. 21 is a flowchart of another manufacturing method of a light-emitting device according to an embodiment of the present disclosure. FIGS. 22 to 30 are sectional views corresponding to steps S420 to S4110 in a manufacturing method of a light-emitting device according to an embodiment of the present disclosure. Referring to FIG. 21, the manufacturing method of a light-emitting device includes the steps below.

In S410, the substrate is provided. The substrate includes a front surface and a back surface opposite to each other.

In S420, the front surface of the substrate is etched to form multiple grooves and multiple protrusion portions. The grooves are multiple v-shaped grooves which are triangular in the cross-section of the substrate perpendicular to the substrate. The grooves are v-shaped grooves. A protrusion portion of the multiple protrusion portions is located between two adjacent v-shaped grooves.

Illustratively, referring to FIG. 22, the front surface of the substrate is etched to form multiple v-shaped grooves 103 which are triangular in the cross-section perpendicular to the substrate. The grooves are v-shaped grooves 103. The protrusion portion is located between two adjacent v-shaped grooves 103.

In S430, a first semiconductor layer, a first active layer, and a second semiconductor layer are formed in sequence in a v-shaped groove and on a protrusion portion. The first element is doped when the first active layer is formed in the v-shaped groove to form a first light-emitting unit in the v-shaped groove and the first element is doped when the first active layer is formed on the protrusion portion to form a second light-emitting unit on the protrusion portion.

Illustratively, referring to FIG. 23, the first semiconductor layer 01, the first active layer 02, and the second semiconductor layer 03 are formed in sequence in the v-shaped groove 103 and on the protrusion portion, and the first element is doped when the first active layer 02 is formed. Since the velocity of the material generated on the sidewall of the v-shaped groove is smaller than the velocity of the material in a planar region, the thickness of the first active layer located on the sidewall of the v-shaped groove is smaller than the thickness of the first active layer 02 located on a top wall (the top surface of a protrusion portion between v-shaped grooves). Since the thickness of the first active layer 02 is small, the corresponding band gap is large, and the emission wavelength is short, the emission wavelength of the first active layer 02 on the side of the v-shaped groove is smaller than the emission wavelength of the first active layer 02 on a protrusion portion. The emission wavelength of the first light-emitting unit 110 formed in the v-shaped groove is smaller than the emission wavelength of the second light-emitting unit 120 formed on the protrusion portion. For materials of the first semiconductor layer 01, the first active layer 02, and the second semiconductor layer 03, reference may be made to the preceding embodiment, and the details are not repeated here.

In S440, the first passivation layer is formed on the front surface of the substrate. The first passivation layer at least covers a surface of the first light-emitting units and the second light-emitting units.

Illustratively, referring to FIG. 24, the first passivation layer 310 is formed on the front surface of the substrate 10. For the function of the first passivation layer 310, reference may be made to step S340, and the details are not repeated here.

In S450, the substrate is turned upside down on the transposition substrate to expose the back surface of the substrate.

Illustratively, referring to FIG. 25, the substrate 10 is turned upside down on the transposition substrate 100 to expose the back surface of the substrate 10.

In S460, the substrate is thinned from the back surface of the substrate.

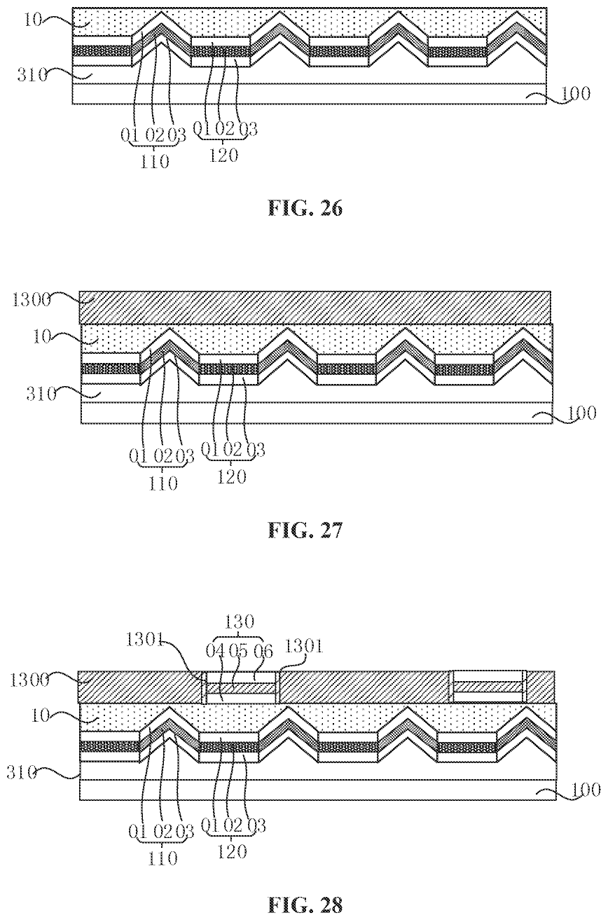

Illustratively, referring to FIGS. 25 and 26, the substrate 10 is thinned from the back surface of the substrate 10. For the effect of thinning the substrate 10, reference may be made to step S360, and the details are not repeated here.

In S470, a third semiconductor layer, a second active layer, and a fourth semiconductor layer are deposited in sequence on the back surface of the substrate to form a third light-emitting unit epitaxial layer.

Illustratively, referring to FIG. 27, the third semiconductor layer, the second active layer, and the fourth semiconductor layer are deposited in sequence on the back surface of the substrate 10 to form the third light-emitting unit epitaxial layer 1300.

In S480, the third light-emitting unit epitaxial layer is etched to form an annular surrounding groove at the edge of the preset position corresponding to each third light-emitting unit in the third light-emitting unit epitaxial layer.

In S490, an insulating material is filled in the annular surrounding groove to form a first insulating bank. A third semiconductor layer, a second active layer, and a fourth semiconductor layer surrounded by each first insulating bank are configured to form a third light-emitting unit.

Illustratively, referring to FIG. 28, the insulating material is filled in the annular surrounding groove to form the first insulating bank 1301. The third semiconductor layer 04, the second active layer 05, and the fourth semiconductor layer 06 in each first insulating bank 1301 are configured to form a third light-emitting unit 130. Illustratively, the conductivity type of the third semiconductor layer 04 is opposite to the conductivity type of the fourth semiconductor layer 06. For materials of the third semiconductor layer 04, the second active layer 05, and the fourth semiconductor layer 06, reference may be made to the preceding embodiment, and the details are not repeated here.

In S4100, the external lead electrodes of at least part of the first light-emitting units, the external lead electrodes of at least part of the second light-emitting units, and the external lead electrodes of at least part of the third light-emitting units are prepared. The vertical projection of a first light-emitting unit having an external lead electrode on the transposition substrate, the vertical projection of a second light-emitting unit having an external lead electrode on the transposition substrate, and the vertical projection of a third light-emitting unit having an external lead electrode on the transposition substrate do not overlap each other.

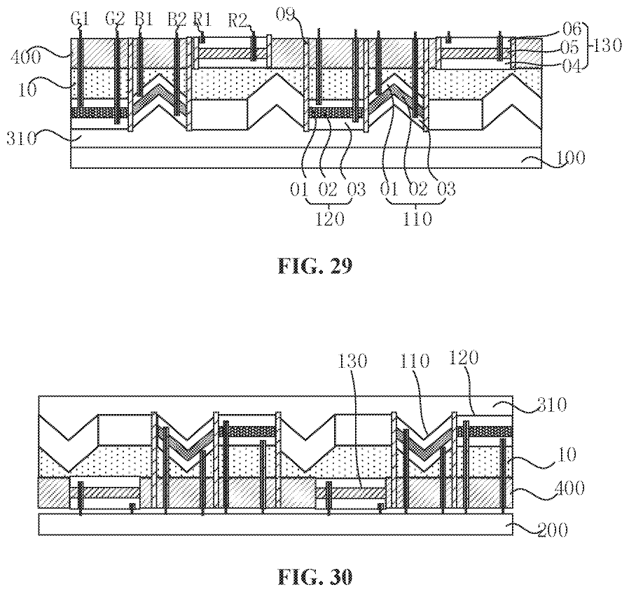

Illustratively, referring to FIG. 29, a first external lead positive electrode B1 and a first external lead negative electrode B2 of the first light-emitting unit 110 are prepared; a second external lead positive electrode G1 and a second external lead negative electrode G2 of the second light-emitting unit 120 are prepared; a third external lead positive electrode R1 and a third external lead negative electrode R2 of the third light-emitting unit 130 are prepared. For the preparation process, reference may be made to step S270, and the details are not repeated here.

Optionally, a second insulating bank 09 is formed between an adjacent first light-emitting unit 110 and second light-emitting unit 120. A second insulating bank 09 is formed between adjacent second light-emitting unit 110 and third light-emitting unit 120. A second insulating bank 09 is formed between adjacent third light-emitting unit 130 and first light-emitting unit 110. In this manner, electrical signal crosstalk between a first light-emitting unit 110, a second light-emitting unit 120, and a third light-emitting unit 130 is prevented.

In S4110, the first light-emitting unit, the second light-emitting unit, and the third light-emitting unit are transferred to the driving substrate through the transposition substrate, and external lead electrodes are connected to connection contact points on the driving substrate in a one-to-one manner.

Illustratively, referring to FIG. 30, the first light-emitting unit 110, the second light- emitting unit 120, and the third light-emitting unit 130 are transferred to the driving substrate 200 through the transposition substrate 100, and external lead electrodes are connected to connection contact points on the driving substrate 200 in a one-to-one manner.

For example, in a light-emitting device manufactured referring to FIGS. 22 to 30, the front surface of the substrate 10 includes protrusion portions and grooves. The grooves include multiple v-shaped grooves 103 disposed at intervals. A protrusion portion is located between two adjacent v-shaped grooves 103. Illustratively, the first light-emitting units 110 are located in the v-shaped grooves 103, the second light-emitting units 120 are located on the protrusion portions. Moreover/Alternatively, the back surface of the substrate 10 includes a third light-emitting unit epitaxial layer 1300, an annular first insulating bank is disposed around the preset position of each third light-emitting unit 130 in the third light-emitting unit epitaxial layer, and the third light-emitting unit epitaxial layer 1300 surrounded by the first insulating bank is configured to form a third light-emitting unit.

Illustratively, first, the third light-emitting unit epitaxial layer is epitaxially formed as a whole. An annular surrounding groove is formed at the edge of the preset position corresponding to each third light-emitting unit in the third light-emitting unit epitaxial layer. The insulating material is filled in the annular surrounding groove to form the first insulating bank. The boundary of a third light-emitting unit is defined by the first insulating bank. The third light-emitting unit epitaxial layer outside of the first insulating bank is retained and does not need to be removed. In this manner, the efficiency of device preparation can be improved.

It is to be noted that in the preceding embodiments, the front surface process of the substrate and the back surface process of the substrate may be combined arbitrarily.

On the basis of the preceding embodiments, optionally, after multiple third light-emitting units 130 are epitaxially formed on the back surface of the substrate 10, the method also includes the steps below.

Optionally, a second passivation layer is formed on the back surface of the substrate 10. The second passivation layer at least covers a surface of the third light-emitting units 130. The third light-emitting units 130 may be protected by the second passivation layer against abrasion to the third light-emitting units 130 during transposition. The material of the second passivation layer may be oxide or nitride, such as at least one of silicon dioxide or silicon nitride. The second passivation layer may be formed by physical vapor deposition or chemical vapor deposition.

Optionally, after the second passivation layer is formed on the back surface of the substrate 10, the method also includes the steps below.

A second insulating bank 09 is formed between adjacent first light-emitting unit 110 and second light-emitting unit 120 to prevent electrical signal crosstalk between the first light-emitting unit 110 and the second light-emitting unit 120. Optionally, the first insulating bank 1301 and the second insulating bank 09 may be manufactured simultaneously. Optionally, part of the first insulating bank 1301 may serve as the second insulating bank 09.

An embodiment of the present disclosure provides a light-emitting device formed by the manufacturing method of a light-emitting device described in any preceding embodiment. Referring to FIG. 9, 20, or 30, the light-emitting device includes a substrate 10, multiple first light-emitting units 110 and multiple second light-emitting units 120, and multiple third light-emitting units 130.

The substrate 10 includes a front surface and a back surface opposite to each other. The front surface includes protrusion portions and grooves.

The multiple first light-emitting units 110 and multiple second light-emitting units 120 are located on the front surface of the substrate 10. The first light-emitting units 110 and the second light-emitting units 120 are located on the protrusion portions and/or in the grooves. The component proportion of the first element in the first light-emitting units 110 is different from the component proportion of the first element in the second light-emitting units 120.

The third light-emitting unit 130 is located on the back surface of the substrate 10.

In the technical solutions provided by the embodiments of the present disclosure, multiple first light-emitting units and multiple second light-emitting units are simultaneously prepared on the front surface of the substrate, thereby improving the production efficiency of the light-emitting device. The third light-emitting units are prepared on the back surface of the substrate. In this manner, light-emitting units of different colors may be transferred to the driving substrate synchronously through the transposition substrate, thereby further improving the production yield of the light-emitting device. Moreover, the first element is doped during the growth of the semiconductor epitaxial layer to form multiple first light-emitting units and multiple second light-emitting units, and the components of the light-emitting layers corresponding to different positions on the front surface are controlled to be different to form the first light-emitting units and the second light-emitting units with different emission wavelengths, therefore there is no need to use phosphor powder or quantum dots for wavelength conversion. Thus, the service life of the light-emitting device is prolonged, and the reliability of the light-emitting device is improved.

It is to be noted that the preceding are only preferred embodiments of the present disclosure and technical principles used therein. Therefore, while the present disclosure has been described in detail through the preceding embodiments, the present disclosure is not limited to the preceding embodiments and may include more other equivalent embodiments without departing from the concept of the present disclosure. The scope of the present disclosure is determined by the scope of the appended claims.

What is claimed is:

1. A manufacturing method of a light-emitting device, comprising:
providing a substrate, wherein the substrate comprises a front surface and a back surface opposite to each other;
performing patterning process on the front surface of the substrate to form a protrusion portion and a groove;
growing a semiconductor epitaxial layer on at least one of following locations: on the protrusion portion, in the groove or on the protrusion portion and in the groove; and forming a first light-emitting unit and a second light-emitting unit by doping a first element during growth of the semiconductor epitaxial layer, wherein a component proportion of the first element in the first light-emitting unit is different from a component proportion of the first element in the second light-emitting unit;
turning the substrate upside down on a transposition substrate to expose the back surface of the substrate; and
forming a third light-emitting unit on the back surface of the substrate.

2. The manufacturing method according to claim 1, wherein the groove comprises a first groove and a second groove, wherein a shape of the first groove is different from a shape of the second groove or a size of the first groove is different from a size of the second groove; and
the forming the first light-emitting unit and the second light-emitting unit comprises:
forming a first semiconductor layer, a first active layer, and a second semiconductor layer in sequence in the first groove and in the second groove; and doping the first element when forming the first active layer in the first groove to form the first light-emitting unit in the first groove and doping the first element when forming the first active layer in the second groove to form the second light-emitting unit in the second groove.

3. The manufacturing method according to claim 2, wherein the shape of the first groove is different from the shape of the second groove,
wherein a bottom surface of the first groove is an inclined surface, and a bottom surface of the second groove is parallel to a plane in which the substrate is located.

4. The manufacturing method according to claim 2, wherein the size of the first groove is different from the size of the second groove,
wherein a notch area of the first groove is larger than a notch area of the second groove.

5. The manufacturing method according to claim 1, wherein the performing patterning process on the front surface of the substrate to form the protrusion portion and the groove comprises:
etching the front surface of the substrate to form a taper protrusion portion which is triangular in a cross-section perpendicular to the substrate, wherein the groove is located between two adjacent taper protrusion portions; and
the forming the first light-emitting unit and the second light-emitting unit comprises:
forming a first semiconductor layer, a first active layer, and a second semiconductor layer in sequence on the taper protrusion portion and in the groove; and doping the first element when forming the first active layer on the taper protrusion portion to form the first light-emitting unit on the taper protrusion portion and doping the first element when forming the first active layer in the groove to form the second light-emitting unit in the groove.

6. The manufacturing method according to claim 1, wherein the performing patterning process on the front surface of the substrate to form the protrusion portion and the groove comprises:
etching the front surface of the substrate to form a v-shaped groove which is triangular in a cross-section perpendicular to the substrate, wherein the protrusion portion is located between two adjacent v-shaped grooves; and
the forming the first light-emitting unit and the second light-emitting unit comprises:
forming a first semiconductor layer, a first active layer, and a second semiconductor layer in sequence in the v-shaped groove and on the protrusion portion, and doping the first element when forming the first active layer in the v-shaped groove to form the first light-emitting unit in the v-shaped groove and doping the first element when forming the first active layer on the protrusion portion to form the second light-emitting unit on the protrusion portion.

7. The manufacturing method according to claim 1, before turning the substrate upside down on the transposition substrate, further comprising:
forming a first passivation layer on the front surface of the substrate, wherein the first passivation layer at least covers a surface of the first light-emitting unit and the second light-emitting unit.

8. The manufacturing method according to claim 1, wherein the forming the third light-emitting unit on the back surface of the substrate comprises:
etching the back surface of the substrate to form a third groove;
forming a third semiconductor layer, a second active layer, and a fourth semiconductor layer in sequence in the third groove to form the third light-emitting unit on the back surface of the substrate.

9. The manufacturing method according to claim 1, wherein the forming the third light-emitting unit on the back surface of the substrate comprises:
forming a mask layer on the back surface of the substrate;
etching the mask layer to form an opening exposing the back surface of the substrate; and
forming a third semiconductor layer, a second active layer, and a fourth semiconductor layer in sequence in the opening to form the third light-emitting unit on the back surface of the substrate.

10. The manufacturing method according to claim 1, wherein the forming the third light-emitting unit on the back surface of the substrate comprises:
depositing a third semiconductor layer, a second active layer, and a fourth semiconductor layer in sequence on the back surface of the substrate to form a third light-emitting unit epitaxial layer;
etching the third light-emitting unit epitaxial layer to form an annular surrounding groove at an edge of a preset position corresponding to the third light-emitting unit in the third light-emitting unit epitaxial layer; and
filling an insulating material in the annular surrounding groove to form a first insulating bank, wherein the third semiconductor layer, the second active layer, and the fourth semiconductor layer surrounded by the first insulating bank are configured to form the third light-emitting unit.

11. The manufacturing method according to claim 1, before forming the third light-emitting unit on the back surface of the substrate, further comprising:
thinning the substrate from the back surface of the substrate.

12. The manufacturing method according to claim 1, after forming the third light-emitting unit on the back surface of the substrate, further comprising:
forming a second passivation layer on the back surface of the substrate, wherein the second passivation layer at least covers a surface of the third light-emitting unit.

13. The manufacturing method according to claim 12, after forming the second passivation layer on the back surface of the substrate, further comprising:
forming a second insulating bank between adjacent first light-emitting unit and second light-emitting unit.

14. A light-emitting device, comprising:
a substrate comprising a front surface and a back surface opposite to each other, wherein the front surface comprises a protrusion portion and a groove;
a first light-emitting unit and a second light-emitting unit located on the front surface of the substrate, wherein the first light-emitting unit and the second light-emitting unit are located on at least one of the following locations: on the protrusion portion, in the groove or on the protrusion portion and in the groove; and a component proportion of a first element in the first light-emitting unit is different from a component proportion of the first element in the second light-emitting unit; and
a third light-emitting unit located on the back surface of the substrate.

15. The light-emitting device according to claim 14, wherein
the groove comprise a first groove and a second groove, wherein a shape of the first groove is different from a shape of the second groove or a size of the first groove is different from a size of the second groove; and the first light-emitting unit is located in the first groove, and the second light-emitting unit is located in the second groove; and/or
the back surface of the substrate comprises a third groove, and the third light-emitting unit is located in the third groove.

16. The light-emitting device according to claim 15, wherein the shape of the first groove is different from the shape of the second groove,
wherein a bottom surface of the first groove is an inclined surface, and a bottom surface of the second groove is parallel to a plane in which the substrate is located.

17. The light-emitting device according to claim 15, wherein the size of the first groove is different from the size of the second groove,
wherein a notch area of the first groove is larger than a notch area of the second groove.

18. The light-emitting device according to claim 15, wherein in a surface perpendicular to a plane in which the substrate is located, a vertical projection of the first groove overlaps a vertical projection of the third groove.

19. The light-emitting device according to claim 14, wherein
the protrusion portion comprises a taper protrusion portion, the groove is located between two adjacent taper protrusion portions, the first light-emitting unit is located on a surface of the taper protrusion portion, and the second light-emitting unit is located in the groove; and/or
the back surface of the substrate is provided with a mask layer, the mask layer comprises an opening exposing the back surface of the substrate, and the third light-emitting unit is located in the opening.

20. The light-emitting device according to claim 14, wherein
the grooves comprise a v-shaped groove, the protrusion portion is located between two adjacent v-shaped grooves, the first light-emitting unit is located in the v-shaped groove, and the second light-emitting unit is located on the protrusion portion; and/or
the back surface of the substrate comprises a third light-emitting unit epitaxial layer, an annular first insulating bank is disposed around a preset position corresponding to the third light-emitting unit in the third light-emitting unit epitaxial layer, and the third light-emitting unit epitaxial layer located in the first insulating bank is configured to form the third light-emitting unit.
